(19) United States
(12) Patent Application Publication
(10) Pub. No.: US 2026/0351518 A1
(43) Pub. Date: Nov. 5, 2026

(54) METHOD INCLUDING DEPOSITION OF TOPOLOGICALLY ETCH-SELECTIVE MATERIAL

(71) Applicant: ASM IP Holding B.V., Almere (NL)

(72) Inventors: Takahiro Arai, Sagamihara-shi (JP); Miguel Sérgio De Abreu Neto, Tokyo (JP); Taishi Ebisudani, Tokyo (JP)

(21) Appl. No.: 19/662,590

(22) Filed: Apr. 29, 2026

Related U.S. Application Data
(60) Provisional application No. 63/798,643, filed on May 2, 2025.

(51) Int. Cl. H01J 37/32; H10P 50/00; H10P 50/28

(52) U.S. Cl. CPC H01J 37/32165; H01J 37/32146; H01J 37/32449; H10P 50/283; H10P 50/73; H01J 2237/332; H01J 2237/334

(57) ABSTRACT

Methods of forming patterned structures suitable for a multiple patterning process are disclosed. Exemplary methods include forming a layer overlying the substrate by providing a precursor to the reaction chamber for a precursor pulse period, providing a reactant to the reaction chamber for a reactant pulse period, applying a first plasma power having a first frequency for a first plasma power period, and applying a second plasma power having a second frequency for a second plasma power period, wherein the first frequency is different than the second frequency.

### CROSS-REFERENCE TO RELATED APPLICATIONS

This application claims priority to U.S. Provisional Patent Application Ser. No. 63/798,643 filed May 2, 2025 and titled METHOD INCLUDING DEPOSITION OF TOPOLOGICALLY ETCH-SELECTIVE MATERIAL, the disclosures of which are hereby incorporated by reference in their entirety.

### FIELD

The present disclosure generally relates to methods and systems for forming patterned structures on a surface of a substrate. More particularly, examples of the disclosure relate to methods that include deposition of topologically etch-selective material, systems for performing such methods, and structures formed using the methods.

### BACKGROUND OF THE DISCLOSURE

During the manufacture of electronic devices, such as semiconductor devices and the like, fine patterns of features can be formed on a surface of a substrate by patterning the surface of the substrate with masking material and removing material from unmasked regions of the substrate surface using, for example, wet etch and/or dry etch processes. Photoresist is often used as the masking material.

A photoresist pattern can be formed by coating a layer of photoresist onto a surface of the substrate, masking the surface of the photoresist, exposing the unmasked portions of the photoresist to radiation, such as ultraviolet light or an electron beam, and removing a portion (e.g., the unmasked or masked portion) of the photoresist, while leaving a portion (e.g., the other of the unmasked or masked portion) of the photoresist on the substrate surface. Once the photoresist is patterned, the patterned photoresist can be used as a template for etching material on the substrate surface in regions in which the photoresist was removed to form a transferred pattern in a layer underlying the photoresist. After etching of the underlying layer, remaining photoresist can be removed.

As a size of features decreases, traditional photoresist techniques may not be suitable to form patterns of desired size. In such cases, multiple patterning techniques can be used to allow for patterning and etching of features that can be smaller than the exposure resolution of the photolithography process. A multiple patterning technique can include forming a spacer about patterned features (e.g., patterned photoresist), removing the patterned features to form patterned structures, and using the patterned structures as a mask during a subsequent etch.

Although such techniques may work relatively well in some applications, removing spacer material between patterned structures generally becomes increasingly difficult as a pitch of the patterned structures decreases. This can be particularly true when anisotropic dry etch processes are used, because charges can build up on a surface of the substrate. Accordingly, improved methods of forming patterned structures on a surface of a substrate are desired. Further, improved device structures, which include the patterned structures, are also desired. Systems for performing the method are also desired.

Any discussion of problems and solutions set forth in this section has been included in this disclosure solely for the purpose of providing context for the present disclosure and should not be taken as an admission that any or all of the discussion was known at the time the invention was made.

### SUMMARY OF THE DISCLOSURE

Various embodiments of the present disclosure relate to methods of forming patterned structures on a surface of a substrate, to the structures formed, and to systems for forming the patterned structures. The patterned structures can be used in the formation of devices, such as semiconductor devices and other electronic devices.

While the ways in which various embodiments of the present disclosure address drawbacks of prior methods and systems are discussed in more detail below, in general, various embodiments of the disclosure provide improved methods of forming patterned structures using deposition of topologically etch-selective material. Methods described herein that include deposition of topologically etch-selective material allow for formation of patterned structures with a relatively small pitch, using a relatively fast etch process, and/or allow for use of an isotropic etch, whereas prior techniques may have desirably used an anisotropic etch.

In accordance with examples of the disclosure, a method including deposition of topologically etch-selective material is disclosed. An exemplary method includes providing a substrate within a reaction chamber of a reactor, providing at least one reactant comprising nitrogen and oxygen to the reaction chamber, providing a group 13 metal precursor to the reaction chamber, providing a first plasma power having a first frequency and a first power within the reaction chamber for a first plasma power pulse, and providing a second plasma power having a second frequency and a second power within the reaction chamber for a second plasma power pulse, wherein the first frequency is less than the second frequency. As set forth in more detail below, use of the first plasma power and the second plasma power allows for formation of topologically etch-selective material—e.g., without a subsequent treatment step. The topologically etch-selective material can be easily selectively removed from, for example, a top and/or bottom, relative to a sidewall, of a feature to form desired patterned structures. In accordance with examples of the disclosure, the steps of providing the first plasma power and providing the second plasma power substantially coincide. In accordance with further examples, the second frequency is ten times or more or twenty times or more the first frequency. In accordance with further examples, the second power is greater than the first power. For example, the second power can be at least 1.5 times greater or at least 2.5 times greater than the first power. In some cases, the second power can be pulsed—e.g., on/high to off/low. A duty ratio of the pulse power can be between about 30 percent and about 70 percent. In accordance with yet further examples, the providing at least one reactant includes providing a nitrogen-containing reactant and providing an oxygen-containing reactant. In such cases, a flowrate of the nitrogen-containing reactant can be greater than a flowrate of the oxygen-containing reactant. For example, the flowrate of the nitrogen-containing reactant can be at least 5 times greater than the flowrate of the oxygen-containing reactant. In accordance with yet further examples, a method does not include an additional trim step to remove the topologically etch-selective material from the top or the bottom. Exemplary methods can further include etching the topologically etch-selective material to selectively remove the topologically etch-selective material from the top and the bottom, relative to the sidewall. The etching can include an isotropic etch process, such as a wet etch process.

In accordance with further embodiments of the disclosure, a device structure is provided. The device structure can be formed according to a method as set forth herein. The device structure can include a substrate and one or more patterned structures formed thereon or therein.

In accordance with yet additional examples of the disclosure, a system is provided. As described in more detail below, the system can include a controller configured to perform a method and/or form a device structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with at least one embodiment of the disclosure.

FIG. 2 illustrates a timing sequence in accordance with at least one embodiment of the disclosure.

FIGS. 3-8 illustrate structures in accordance with exemplary embodiments of the disclosure.

FIG. 9 illustrates a reactor system in accordance with at least one embodiment of the disclosure.

FIG. 10 illustrates another reactor system in accordance with at least one embodiment of the disclosure in accordance with examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particularly disclosed embodiments described below.

The present disclosure generally relates to methods of forming patterned structures on a surface of a substrate, to device structures including the patterned structures, and to systems for performing the methods and/or forming the device structures. The patterned structures can be used as an etch mask or as patterned features for formation of a next set of patterned structures. As described in more detail below, exemplary methods can be used to form structures suitable for forming electronic devices.

In this disclosure, gas may include material that is a gas at normal temperature and pressure, a vaporized solid and/or a vaporized liquid, and may be constituted by a single gas or a mixture of gases, depending on the context. A gas other than the process gas, e.g., a gas introduced without passing through a gas distribution assembly, such as a showerhead, other gas distribution device, or the like, may be used for, e.g., sealing the reaction space, and may include a seal gas, such as a rare or other inert gas. The term inert gas refers to a gas that does not take part in a chemical reaction to an appreciable extent and/or a gas that can excite a precursor when plasma power is applied. In some cases, the terms precursor and reactant can be used interchangeably.

As used herein, the term substrate can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various features, such as recesses, lines, and the like formed within or on at least a portion of a layer of the substrate. By way of particular examples, a substrate can include bulk semiconductor material and/or a layer to be etched.

In some embodiments, film refers to a layer extending in a direction perpendicular to a thickness direction to cover an entire target or concerned surface, or simply a layer covering a target or concerned surface. In some embodiments, layer refers to a structure having a certain thickness formed on a surface or a synonym of film or a non-film structure. A layer can be continuous or noncontinuous. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequences, and/or functions or purposes of the adjacent films or layers.

A feature can refer to a protrusion above a surface of a substrate or a recess that extends into the substrate. A protrusion can be a pillar, line, or the like. A recess can be a via, trench, or the like.

In this disclosure, continuously can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments. For example, a reactant and/or an inert gas can be supplied continuously during two or more steps and/or deposition cycles of a method.

The term cyclic deposition process or cyclical deposition process can refer to the sequential introduction of precursors (and/or reactants) and/or pulsing of plasma power into or within a reaction chamber to deposit a layer over a substrate and includes processing techniques, such as atomic layer deposition (ALD), cyclical chemical vapor deposition (cyclical CVD), hybrid cyclical deposition processes that include an ALD component and a cyclical CVD component, and plasma-enhanced variations thereof.

As used herein, the term atomic layer deposition (ALD) may refer to a vapor deposition process in which deposition cycles, preferably a plurality of consecutive or continuous deposition cycles, are conducted in a process chamber. Typically, during each cycle, a precursor is introduced and may be chemisorbed to a deposition surface (e.g., a substrate surface or a previously deposited underlying surface, such as material from a previous ALD cycle), forming a monolayer or sub-monolayer that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. Purging steps may be utilized during each cycle to remove excess precursor from the process chamber and/or remove excess reactant and/or reaction byproducts from the process chamber after conversion of the chemisorbed precursor. Further, the term atomic layer deposition, as used herein, is also meant to include processes designated by related terms, such as chemical vapor atomic layer deposition, when performed with alternating pulses of precursor(s), reactant(s), and purge (e.g., inert carrier) gas(es). PEALD refers to an ALD process, in which a plasma is applied during one or more of the ALD steps.

As used herein, the term purge may refer to a procedure in which an inert or substantially inert gas is provided to a reactor chamber in between two pulses of gases that might otherwise react with each other. For example, a purge may be provided between a precursor pulse and a plasma pulse, thus avoiding or at least reducing gas phase interactions between the precursor and an activated reactant. It shall be understood that a purge can be effected either in time or in space, or both. For example, in the case of temporal purges, a purge step can be used, e.g., in the temporal sequence of providing a first precursor to a reactor chamber, providing a purge gas to the reactor chamber, and providing a second precursor or reactant to the reactor chamber, wherein the substrate on which a layer is deposited does not move. In the case of spatial purges, a purge step can, for example, take the following form: moving a substrate from a first location to which a first precursor is supplied, through a purge gas curtain, to a second location to which a second precursor is supplied.

As used herein, metal oxide refers to a material that includes at least one metal and oxygen. A metal oxide can be represented by the formula MOₓ, where M represents a metal (e.g., TiO₂). In some cases, the metal oxide may not be or include stoichiometric metal oxide. In some cases, the metal oxide can include other elements, such as carbon, nitrogen, hydrogen, or the like. Exemplary metals include group 13 metals, such as titanium.

As used herein, the term overlap can mean coinciding with respect to time and within a reaction chamber. For example, when two or more plasma power periods overlap, there is a period of time in which power for each of the two or more plasma power periods is provided to a reaction chamber. Similarly, with regard to gas pulse periods, such as precursor pulse periods and reactant pulse periods, two or more gas pulse periods can overlap when gas from the respective pulse periods is within the reaction chamber or provided to the reaction chamber for a period of time.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. For example, the term about can refer to +/−20, 10, 5, 2, or 1 percent of a value. The terms comprising, including, constituted by and having refer independently to typically or broadly comprising, comprising, consisting essentially of, or consisting of in some embodiments. In this disclosure, any defined meanings do not necessarily exclude ordinary and customary meanings, in some embodiments.

Although a number of example materials are given throughout the embodiments of the current disclosure, it should be noted that the chemical formulas given for each of the example materials should not be construed as limiting. Unless otherwise noted, the non-limiting example materials given should not be limited by a given example stoichiometry.

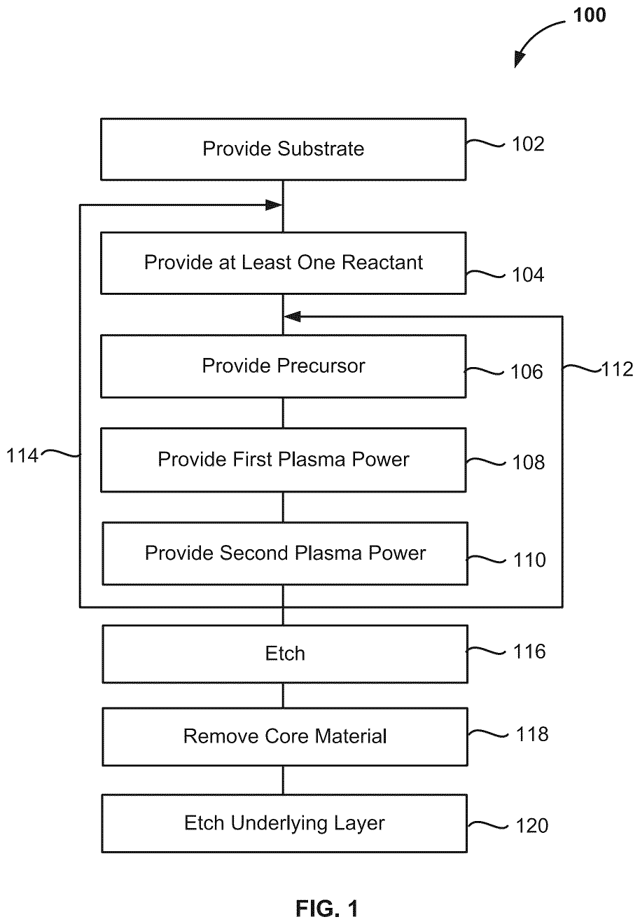

Turning now to the figures, FIG. 1 illustrates a method 100 including deposition of topologically etch-selective material in accordance with examples of the disclosure. Method 100 can be used for a variety of purposes, such as, for example, forming patterned structures (e.g., using a multiple patterning process). As illustrated, method 100 includes the steps of providing a substrate within a reaction chamber of a reactor, the substrate comprising at least one feature (step 102), providing at least one reactant (step 104), providing a group 13 metal precursor to the reaction chamber (step 106), providing a first plasma power (step 108), and providing a second plasma power (step 110). Method 100 can also include an etch (step 116), removing mandrels (step 118), and etching an underlayer (step 120). Although illustrated with steps 102-120, exemplary methods need not include all such steps but rather can include any subset of the steps.

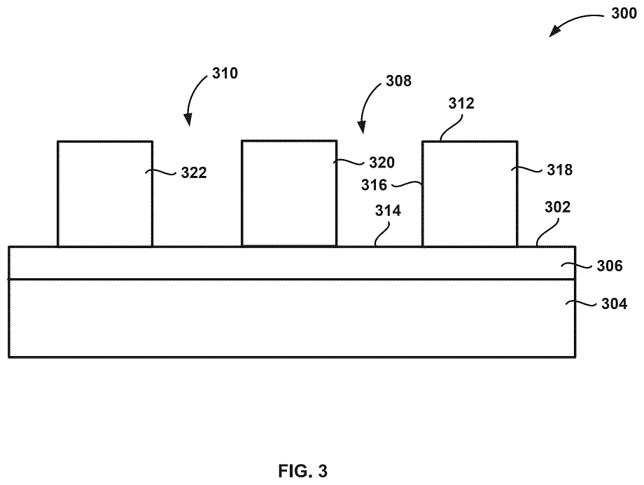

During step 102, a substrate comprising a surface comprising at least one feature is provided within a reaction chamber of a reactor system. An exemplary substrate 300 for use during step 102 is illustrated in FIG. 3. In this example, the substrate includes a first layer or bulk material 304, a second layer 306 (e.g., a layer to be etched), and a surface 302, including patterned features 308, 310. First layer or bulk material 304 can include, for example, silicon or other semiconductor material; second layer 306 can include, for example, one more materials having etching selectivity against materials (e.g., metal oxides) used to form patterned structures. With reference to feature 308, one or more features can include a top 312, a bottom 314, and a sidewall 316 (e.g., spanning) therebetween. Features 308, 310, can be recesses, trenches, vias, or the like and can be defined, at least in part, by mandrels 318, 320, 322. Mandrels 318, 320, 322 can be formed or include, for example, one or more of photoresist, carbon hardmask material, amorphous silicon, amorphous carbon, polysilicon, or the like.

Returning again to FIG. 1, the reaction chamber used during step 102 can be or include a reaction chamber of a chemical vapor deposition reactor system configured to perform a cyclical deposition process. The reaction chamber can be a standalone reaction chamber or part of a cluster tool. Exemplary reaction chambers suitable for use with step 102 are described in more detail below.

Step 102 can include heating the substrate to a desired deposition temperature within the reaction chamber. In some embodiments of the disclosure, step 102 includes heating the substrate to a temperature of less than 400 °C. For example, in some embodiments of the disclosure, heating the substrate to a deposition temperature may comprise heating the substrate to a temperature between approximately 50 °C and approximately 400 °C or between about 20 °C and about 250 °C or between about 40 °C and about 220 °C. In addition to controlling the temperature of the substrate, a pressure within the reaction chamber may also be regulated. For example, in some embodiments of the disclosure, the pressure within the reaction chamber during step 102 may be less than 760 Torr or between 0.2 Torr and 760 Torr or between about 1.5 Torr and 10 Torr. In some cases, a pressure within the reaction chamber is greater than 400 Pa or between greater than 400 Pa and about 500 Pa or between about 100 Pa and about 500 Pa or between about 200 Pa and about 400 Pa during step 102 and/or steps 104-110.

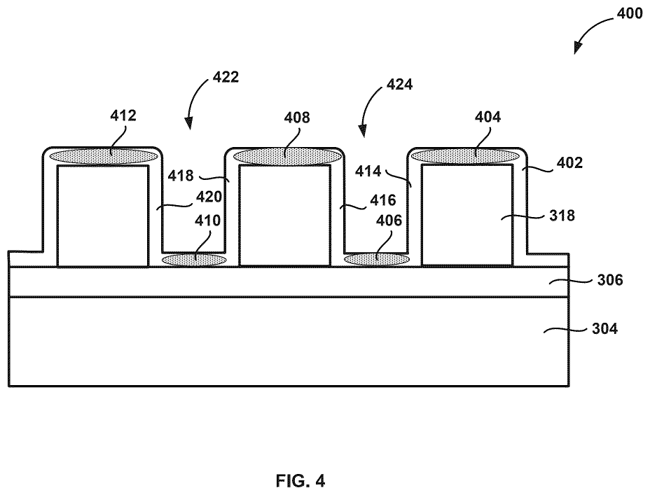

During steps 104-110, a layer (e.g., layer 402, illustrated in FIG. 4) is formed overlying the substrate provided in step 102. Layer 402 can be or include, for example, a metal oxide, such as a group 13 metal oxide. Layer 402 can be relatively thin, e.g., less than about 20 nm. Layer 402 can exhibit a high etch selectivity, relative to layer 306.

In accordance with examples of the disclosure, steps 104-110 are used to deposit topologically etch-selective material. Steps 104-110 or steps 106-110 can be repeated one or more times as illustrated by cycles 114 (e.g., including steps 104-110) and 112 (e.g., including steps 106-110, with step 104 continuing through steps 106-110). Further, one or more steps 104-110 can be repeated one or more times prior to method 100 proceeding to the next step.

During step 104, at least one reactant comprising nitrogen and oxygen is provided to the reaction chamber. Exemplary reactants that include nitrogen and oxygen include, for example, N₂O, N₂O₂, NO₂, and the like. In some cases, the providing at least one reactant includes providing a nitrogen-containing reactant and providing an oxygen-containing reactant. The nitrogen-containing reactant can include, for example, N₂, N₂O, N₂O₂, NO₂, or the like. The oxygen-containing reactant can include, for example, O₂, CO₂, O₃, CO, N₂O, N₂O₂, NO₂, or the like. In accordance with examples of the disclosure, a flowrate of the nitrogen-containing reactant is greater than a flowrate of the oxygen-containing reactant. For example, a volumetric flow ratio and/or an atomic ratio of N to O can be at least 5. A reactant can be provided continuously during (e.g., before, during, and after) one or more deposition cycles 112 or 114. A reactant gas flowrate may be in a range of about 100 to about 10000 sccm.

During step 106, a group 13 metal precursor is provided to the reaction chamber for a metal precursor pulse. Exemplary metal precursors can include an alkoxide and/or alkylamino compounds. For example, a titanium precursor can be at least one compound selected from titanium alkoxide and alkylamino titanium. By way of particular examples, the precursor can be or include one or more of Ti(OR)₄ wherein R is independently CₓH_{y} (x=0, 1, 2, 3, 4, or 5, y=2ₓ₊₁), and each R can be different (e.g., Ti(OCH₃)₂(OC₂H₅)(OC₃H₇)); Ti(NR₂)₄ wherein R is independently CₓH_{y} (x=0, 1, 2, 3, 4, or 5, y=2ₓ₊₁), and each R can be different (e.g., Ti(N(CH₃)(C₂H₅))₄). A precursor for a metal oxide other than titanium oxide can also be selected from any suitable compounds. In general, an alkylamino precursor, such as tetrakis-dimethylaminotitanium (TDMAT), can provide a higher film growth rate than does an alkoxy precursor, such as titanium tetraisopropoxide (TTIP), because a precursor having a smaller molecular size, such as TDMAT, tends to have less steric hindrance, so as to have more adsorption sites as compared with a precursor having a greater molecular size, such as TTIP. A precursor with a carrier gas flowrate may be in a range of about 500 to about 5000 sccm. A duration of step 106 can range from about 0.05 to about 5 seconds.

During steps 108 and/or 110, a plasma is formed. The plasma may be a direct plasma—formed within the reaction chamber.

During step 108, a first plasma power having a first frequency and a first power is provided within the reaction chamber for a first plasma power pulse. In accordance with examples described herein, the frequency of the power provided during step 108 is lower than a frequency of the power provided during step 110. For example, the frequency of power provided during step 108 can be less than 1 MHz or less than 500 kHz. For example, the frequency of power provided during step 108 can be 430 kHz. In accordance with further examples, the power provided during step 108 can be pulsed on and off and/or pulsed high and low (e.g., 20% or less than high power value). A duty ratio of the pulsed power can be between about 30 percent and about 70 percent for one or more (e.g., a plurality of) cycles. The duty ratio can be defined as a percent of plasma power on-time/(on-time+off-time); on and off can be replaced with high and low in the preceding equation. A frequency of the plurality of cycles can be between about 1 kHz and about 30 kHz. In accordance with yet further examples, the first power may be at least 50 W.

During step 110, a second plasma power having a second frequency and a second power is provided within the reaction chamber for a second plasma power pulse. As noted above, the second frequency can be greater than the first frequency. For example, the second frequency can be ten times or more or twenty times or more the first frequency or be between about 10 and 200 times greater than the first frequency. By way of examples, the second frequency can be greater than 1 MHz or greater than 10 MHz or between about 10 MHz and about 100 MHz. In accordance with various examples, the second power is greater than the first power. For example, the second power can be at least 1.5 times greater or at least 2.5 times greater than the first power or be between about 1×and about 20× greater than the first power. By way of examples, the second power can be between at least 50 W. As discussed in more detail below, steps 108 and 110 of providing the first plasma power and providing the second plasma power substantially coincide.

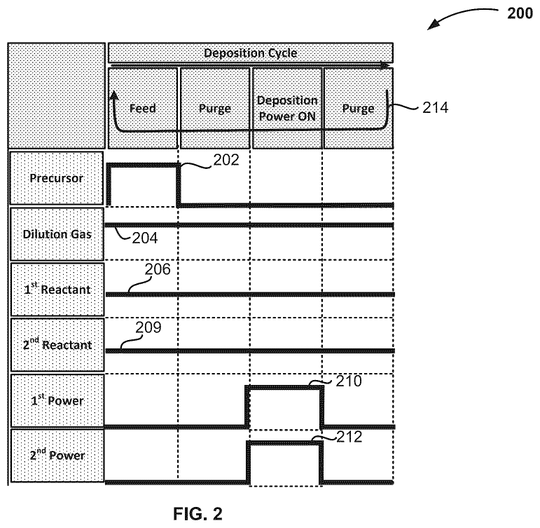

FIG. 2 illustrates a timing sequence 200 suitable for use as steps 104-110 of method 100. Timing sequence 200 is meant to be illustrative and not necessarily restrictive of the description of method 100.

During sequence 200, a precursor is provided during a precursor pulse 202. The precursor, flowrate, and/or pulse duration can be as described above.

Although not illustrated in FIG. 1, method 100/sequence 200 can include providing a dilution gas to the reaction chamber, as illustrated by step 204. Exemplary dilution gases include, for example, argon, nitrogen, or helium in any combination. A flowrate of the dilution gas to the reaction chamber can be between about 0.1 and about 100 SLM or between about 0.5 and 5 SLM. Step 204 can begin prior to step/pulse 202. In some cases, the dilution gas can also be a carrier gas used to provide the precursor during precursor pulse 202.

Steps 206 and 208 can be the same or similar to step 104 as described above. In the example illustrated in FIG. 2, a first reactant and a second reactant are provided continuously through one or more deposition cycles 214.

As illustrated in FIG. 2, in some cases, the step of applying the first plasma power (first plasma power period 210) and the step of applying the second plasma power (second plasma power period 212) overlap. In some cases, steps 210 and 212 substantially coincide (e.g., start and/or end within 0.1 seconds or less of each other).

Table 1 illustrates exemplary process conditions in accordance with particular examples of the disclosure. The table is meant to illustrate exemplary conditions and not necessarily limit the scope of the disclosure.

TABLE 1

| Conditions | | Set point | Exemplary range |
|---|---|---|---|
| Oxygen-containing reactant | [slm] | 0.2 | 0.1-2 |
| Nitrogen-containing reactant | [slm] | 2.0 | 0.1-100 |
| Dilution gas (e.g., Ar) | [slm] | 1.0 | 0.1-100 |
| Carrier gas (e.g., Ar) | [slm] | 2.0 | 0.1-10 |
| RC Press. | [Pa] | 270 | 50-1000 |
| Second power | [W] | 244 | 50-1500 |
| First power | [W] | 100 | 50-1500 |
| Electrode gap | [mm] | 12 | 6-15 |
| Depo sequence [sec] | Feed | 0.60 | 0.1-1.0 |
| | Purge | 0.45 | 0.1-2.0 |
| | RF ON | 0.60 | 0.1-60 |
| | Purge | 0.15 | 0.1-2.0 |

FIG. 4 illustrates a structure 400 after completion of steps 102-110/sequence 200. Structure 400 is similar to structure 300, except structure 400 includes a topologically etch-selective material layer 402 deposited onto structure 300. Topologically etch-selective material layer 402 includes regions 404-412, of which the film quality is relatively poor, and regions 414-420, of which the film quality is relatively good or high. As illustrated, topologically etch-selective regions 404, 408, 412 can be located at a top of features 422, 424, topologically etch-selective regions 406, 410 can be located at a bottom of features 422, 424, and relatively etch-resistant regions 414-420 can be formed along (e.g., spanning) sidewalls of the respective features (e.g., sidewall 316). A thickness of layer 402 can be conformal. In this context, conformal can mean a step coverage equal to or greater than about 50%, or greater than about 80%, or greater than about 90%, or greater than about 95%, or greater than about 98%, or even above 100%. In this context, step coverage can be defined as the ratio of layer thickness along the sidewalls or bottom of a feature to the thickness of the layer in the open area without features. A density or film quality of layer 402 is not conformal. For example, etch rate (e.g., using an etch process described below) of regions 406, 410 and/or regions 404, 408, 412 can be 2, 3, 5, or more times greater than an etch rate of layer in regions 414-420.

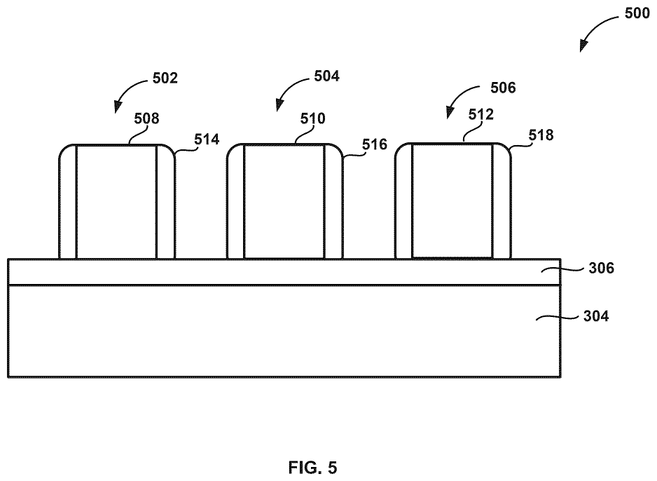

Returning to FIG. 1, once steps 104-110 (e.g., timing sequence 200) are complete, portions of the layer 402 (e.g., in regions 404, 406, 408, 410, and 412) are selectively removed during step 116 to form structure 500, including patterned structures 502-506, as illustrated in FIG. 5. Patterned structures 502-506 include mandrels or cores 508-512 (e.g., as described above in connection with FIG. 3) and spacers 514-518 on the respective sidewalls of mandrels/cores 508-512.

Portions of layer 402 can be selectively removed using any suitable wet or dry etch. Step 116 can include etching the topologically etch-selective material to selectively remove the topologically etch-selective material from the top and the bottom, relative to the sidewall. A wet etch process may include fluorinated chemistries (e.g., HF) or SC1 solutions, or alternatively any wet chemical etching formulation—whether acidic, alkaline, oxidizing, reducing, chelating, or surfactant-enhanced—that may provide a selectivity greater than approximately 5:1 between the target material and surrounding materials. For films of uniform quality (of which layer 402 is not), wet etch processes are generally considered isotropic. A dry etch process can include using activated fluorine. A reactant during the dry etch process can include, for example, NF₃ at about 50 °C to about 300 °C. Because regions 404, 406, 408, 410, and 412 are of different film quality than regions 414-420, a typically isotropic etch (for a film of uniform quality) can be used to selectively remove portions of layer 402 in regions 404, 406, 408, 410, and 412, relative to regions 414-420.

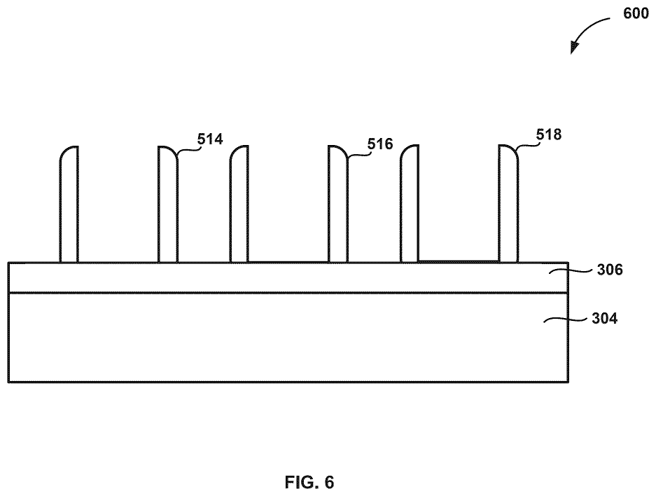

During step 118, mandrels/cores 508-512 can be removed. For example, an ashing process can be used to remove mandrels 508-512 to form device structure 600, as illustrated in FIG. 6.

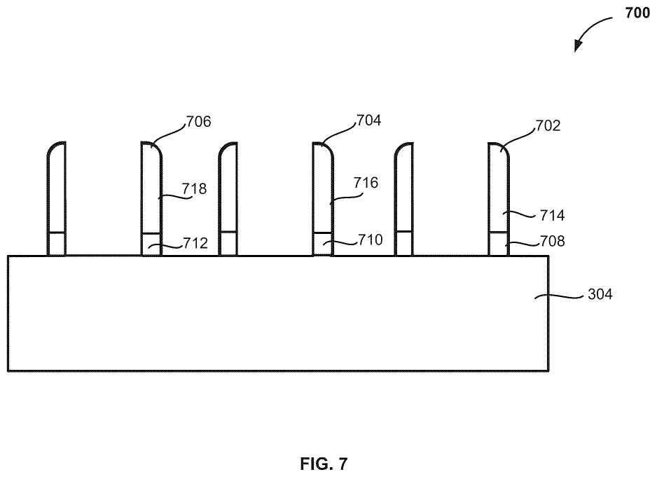

During step 120, layer 306 can be etched using spacers 514-518 as a templated mask to form device structure 700, as illustrated in FIG. 7. Device structure 700 includes bulk material/substrate 304 and patterned structures 702-706 formed thereon. Structures 702-706 include regions 708-712 that include material from layer 306 and regions 714-718 that include spacer material (e.g., a group 13 metal oxide). Any suitable etch process can be used to form structures 702-706 and will generally depend on the composition of layer 306.

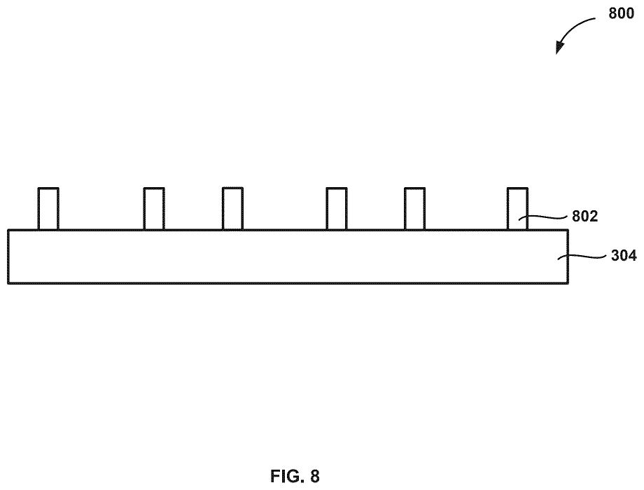

Finally, although not separately illustrated in FIG. 1, any remaining spacer material can be removed using a suitable etch to form structure 800 illustrated in FIG. 8. Structure 800 includes features 802 formed of material from layer 306.

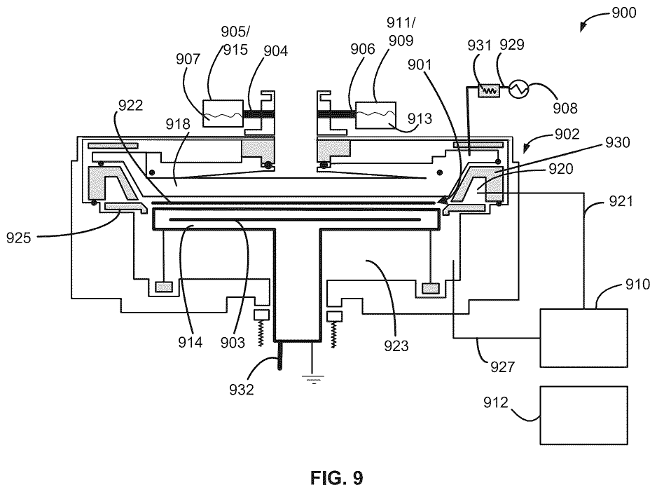

A reactor system 900 in accordance with exemplary embodiments of the disclosure is illustrated in FIG. 9. Reactor system 900 can be used to perform one or more steps or substeps as described herein and/or to form one or more structures or portions thereof as described herein.

Reactor system 900 includes a pair of electrically conductive flat-plate electrodes 914, 918 in parallel and facing each other in an interior 901 (reaction zone) of a reaction chamber 902. A plasma can be excited within reaction chamber 902 by applying, for example, plasma power from plasma power source(s) (i.e., at least one power source) 908 to one electrode (e.g., electrode 918) and electrically grounding the other electrode (e.g., electrode 914). Power source(s) 908 can be coupled to electrode 918 via a transmission line 929 and an RF filter 931. As noted above, power source(s) 908 can suitably be configured to provide plasma power at a first frequency and at a second frequency, coupled to the reaction chamber. The first frequency can additionally be pulsed as described above.

A temperature regulator 903 can be provided in a lower stage 914 (the lower electrode), and a temperature of a substrate 922 placed thereon can be kept at a desired temperature, such as the temperatures noted above. Electrode 918 can serve as a gas distribution device, such as a shower plate or showerhead. Precursor gases, reactant gases, and a carrier or inert gas, if any, or the like can be introduced into reaction chamber 902 using one or more gas lines (e.g., reactant gas line 904 and precursor gas line 906, respectively, coupled to a reactant source and a precursor source). For example, an inert gas and a reactant from at least one reactant source 915 comprising a vessel 905 and the reactant 907 therein can be introduced into reaction chamber 902 using line 904 and/or a precursor from a precursor source 909 comprising a first vessel 911 and a group 13 metal precursor 913 therein, coupled to the reaction chamber, and a carrier gas (e.g., an inert gas as described above) can be introduced into the reaction chamber 902 using line 906. Although illustrated with two inlet gas lines 904, 906, reactor system 900 can include any suitable number of gas lines.

In reaction chamber 902, a circular duct 920 with an exhaust line 921 can be formed within a duct plate 930, through which gas in the interior 901 of reaction chamber 902 can be exhausted to an exhaust source 910. Additionally, a transfer chamber 923 can be provided with a seal gas line 932 to introduce seal gas into the interior 901 of reaction chamber 902 via the interior (transfer zone) of transfer chamber 923, wherein a separation plate 925 for separating the reaction zone 901 and the transfer chamber 923 can be provided (a gate valve through which a substrate is transferred into or from transfer chamber 923 is omitted from this figure). Transfer chamber 923 can also be provided with an exhaust line 927 coupled to exhaust source 910. In some embodiments, continuous flow of a carrier gas to reaction chamber 902 can be accomplished using a flow-pass system (FPS).

Reactor system 900 can include one or more controller(s) 912 programmed or otherwise configured to cause one or more method steps as described herein to be conducted. Controller(s) 912 are coupled with the various power sources, heating systems, pumps, robotics and gas flow controllers, or valves of the reactor, as will be appreciated by the skilled artisan. By way of example, controller 912 can be configured to control gas flow of a precursor, a reactant, and an inert gas into at least one of the one or more reaction chambers to form a layer on a surface of a substrate. Controller 912 can be further configured to provide power to form a plasma—e.g., within reaction chamber 902. Controller 912 can be similarly configured to perform additional or alternative steps as described herein. By way of examples, controller 912 can be configured to provide the precursor for a precursor pulse to the reaction chamber, provide at least one reactant to the reaction chamber, and provide the plasma power at the first frequency and provide the plasma power at the second frequency for a plasma pulse to form a topologically etch-selective material on a surface of a substrate.

Controller 912 can include electronic circuitry and software to selectively operate valves, manifolds, heaters, pumps and other components included in system 900. Such circuitry and components operate to introduce precursors, reactants, and purge gases from the respective sources. Controller 912 can control timing of gas pulse sequences, temperature of the substrate and/or reaction chamber, pressure within the reaction chamber, and various other operations to provide proper operation of the system 900.

Controller 912 can include control software to electrically or pneumatically control valves to control flow of precursors, reactants, and/or purge gases into and out of the reaction chamber 902. Controller 912 can include modules, such as a software or hardware component, e.g., a FPGA or ASIC, which performs certain tasks. A module can advantageously be configured to reside on the addressable storage medium of the control system and be configured to execute one or more processes.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

During operation of system 900, substrates, such as semiconductor wafers, are transferred from, e.g., a substrate handling area 923 to the reaction zone 901. Once substrate(s) are transferred to reaction zone 901, one or more gases, such as precursors, reactants, carrier gases, and/or purge gases, are introduced into reaction chamber 902.

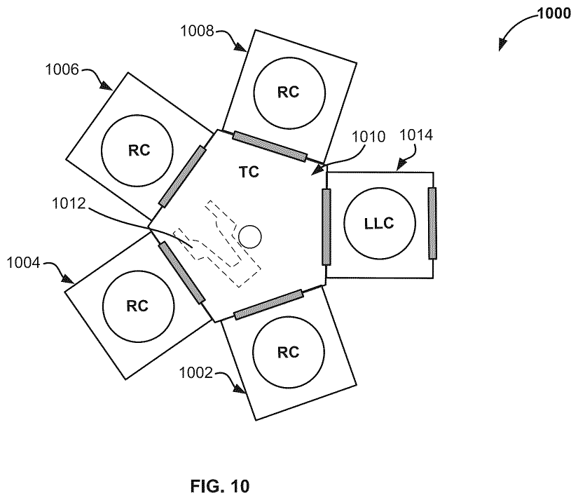

FIG. 10 illustrates a reactor system 1000 that includes a plurality of reaction chambers 1002-1008, each of which can be an example of reaction chamber 902 in FIG. 9 or can be part of a dual or quad reaction chamber module. Reaction chambers 1002-1008 can be disposed around and/or coupled to a transfer chamber 1010 that includes a transfer tool 1012 for transferring substrates between reaction chambers 1002-1008 and a load lock chamber 1014, and between reaction chambers 1002-1008 (e.g., through transfer chamber 1010). For example, a substrate 922 can be disposed in different chambers for different steps of a method described herein.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

1. A method including deposition of topologically etch-selective material, the method comprising the steps of:
providing a substrate within a reaction chamber of a reactor, the substrate comprising at least one feature comprising a top, a bottom, and a sidewall therebetween;
providing at least one reactant comprising nitrogen and oxygen to the reaction chamber;
providing a group 13 metal precursor to the reaction chamber for a metal precursor pulse;
providing a first plasma power having a first frequency and a first power within the reaction chamber for a first plasma power pulse; and
providing a second plasma power having a second frequency and a second power within the reaction chamber for a second plasma power pulse,
wherein the first frequency is less than the second frequency.

2. The method of claim 1, wherein the steps of providing the first plasma power and providing the second plasma power substantially coincide.

3. The method of claim 1, wherein the second frequency is ten times or more or twenty times or more the first frequency.

4. The method of claim 1, wherein the first frequency is less than 1 MHz.

5. The method of claim 1, wherein the second frequency is greater than 1 MHz.

6. The method of claim 1, wherein the first power is between about 50 W and about 1500 W or at least 50 W.

7. The method of claim 1, wherein the second power is between about 50 W and about 1500 W or at least 50 W.

8. The method of claim 1, wherein the second power is greater than the first power.

9. The method of claim 1, wherein the second power is at least 1.5 times greater or at least 2.5 times greater than the first power.

10. The method of claim 1, wherein the first power is pulsed on and off at a duty ratio between about 30 percent and about 70 percent for a plurality of cycles.

11. The method of claim 10, wherein a frequency of the plurality of cycles is between about 1 kHz and about 30 kHz.

12. The method of claim 1, wherein the providing at least one reactant comprises:
providing a nitrogen-containing reactant; and
providing an oxygen-containing reactant.

13. The method of claim 12, wherein a flowrate of the nitrogen-containing reactant is greater than a flowrate of the oxygen-containing reactant.

14. The method of claim 13, wherein the flowrate of the nitrogen-containing reactant is at least 5 times greater than the flowrate of the oxygen-containing reactant.

15. The method of claim 1, wherein the group 13 metal precursor comprises titanium.

16. The method of claim 1, wherein the method does not include an additional trim step to remove the topologically etch-selective material from the top or the bottom.

17. The method of claim 1, further comprising etching the topologically etch-selective material to selectively remove the topologically etch-selective material from the top and the bottom, relative to the sidewall.

18. The method of claim 17, wherein the etching comprises an isotropic etch process.

19. A structure formed according to the method of claim 1.

20. A reactor system comprising:
a reaction chamber;
a precursor source, comprising a vessel and group 13 metal precursor therein, coupled to the reaction chamber;
at least one reactant source coupled to the reaction chamber;
at least one plasma power source, configured to provide plasma power at a first frequency and at a second frequency, coupled to the reaction chamber; and
a controller configured to:
provide the precursor for a precursor pulse to the reaction chamber;
provide at least one reactant to the reaction chamber; and
provide the plasma power at the first frequency and provide the plasma power at the second frequency to form a topologically etch-selective material on a surface of a substrate.
